(19) United States
(12) Patent Application Publication
(10) Pub. No.: US 2013/0309512 A1
(43) Pub. Date: Nov. 21, 2013

(54) CURABLE RESIN COMPOSITION, CURED PRODUCT, SURFACE TREATED CURED PRODUCT, AND LAMINATE

(71) Applicants: Makoto Fujimura, Tokyo (JP); Takashi Iga, Tokyo (JP)

(72) Inventors: Makoto Fujimura, Tokyo (JP); Takashi Iga, Tokyo (JP)

(73) Assignee: ZEON CORPORATION, Chiyoda-ku (JP)

(21) Appl. No.: 13/997,928

(22) PCT Filed: Dec. 27, 2011
(86) PCT No.: PCT/JP2011/080153

§ 371 Date: Jun. 25, 2013

(30) Foreign Application Priority Data
Dec. 27, 2010 (JP) 2010-290061

(51) Int. Cl. H05K 1/02

(52) U.S. Cl. CPC H05K 1/0296
USPC 428/458; 524/99

(57) ABSTRACT

A curable resin composition comprised of an alicyclic olefin polymer (A) which has polar groups, a curing agent (B), a hindered phenol compound (C), and a hindered amine compound (D) is provided. According to the curable resin composition of the present invention, it is possible to give a cured product which is small in surface roughness when treated on its surface by an aqueous solution of a permanganate, which is excellent in adhesion to a conductor layer, which is high in peel strength, and which is excellent in electrical characteristics.

### TECHNICAL FIELD

The present invention relates to a curable resin composition, cured product, surface treated cured product, and laminate.

### BACKGROUND ART

Along with the pursuit of smaller sizes, more diverse functions, higher speed communications, etc. in electronic equipment, further higher densities of the circuit boards which are used in such electronic equipment are being demanded. To meet with such demands for higher density, circuit boards are being made multilayered in configuration. Such multilayer circuit boards are, for example, formed by taking an inner layer board which is comprised of an electrical insulating layer and a conductor layer formed on its surface, laminating an electrical insulating layer on it, forming a conductor layer on this electrical insulating layer, and further repeating the lamination of electrical insulating layers and formation of conductor layers.

The interconnect rule in multilayer circuit boards has become finer with each passing year. In particular, this trend has become remarkable in applications such as interposer boards or semiconductor package boards for semiconductor packages. 25 μm or less interconnect widths and pitches are being demanded. The demands on such printed circuit boards for semiconductor packages are entering an area difficult to realize with the current representative method of forming fine interconnects of the semi-additive process.

When forming fine interconnects on an electrical insulating layer, the roughness of the insulating layer surface has a great effect on the ability to form interconnects or the reliability. If the surface of an insulating layer is large in roughness, sometimes the conductor is left between patterns due to poor etching or the conductor blisters or peels off. Furthermore, due to the effects of the plating catalyst residue, poor insulation easily occurs. Conversely, if the surface of a insulating layer is small in roughness, the bonding strength of the plating metal becomes smaller and peeling of the conductor occurs or there are other effects on reliability. For this reason, in high density patterns, it is important that the roughness be low and the adhesion with the plating metal be good.

Furthermore, if roughening the surface of an electrical insulating layer, the problem ends up arising of a delay in transmission due to the skin effect at the high frequency region, so art is being studied for improving the adhesion between an electrical insulating layer and conductor layer without roughening the surface of the electrical insulating layer.

As such art, for example, Patent Document 1 discloses using a curable resin composition which contains an alicyclic olefin polymer or other insulating polymer and a curing agent so as to form an uncured or semicured resin layer, bringing a compound which has a structure able to coordinate with a metal into contact with the surface of the resin layer which is formed, and curing the result so as to thereby form an electrical insulating layer and treating the surface by an aqueous solution of permanganate so as to thereby obtain an electrical insulating layer which is excellent in electrical characteristics, smooth, and excellent in adhesion with a conductor layer.

Further, Patent Document 2 discloses a resin composition which contains a hindered compound in 3 to 50 parts by weight with respect to 100 parts by weight of an alicyclic structure-containing polymer as a resin composition which is excellent in adhesion with respect to circuit boards or electronic components having fine surface relief and which is excellent in long term reliability.

### PRIOR ART DOCUMENTS

### Patent Documents

Patent Document 1: Japanese Patent Publication No. 2003-158373
Patent Document 2: Japanese Patent Publication No. 11-293127

### DISCLOSURE OF THE INVENTION

### Problem to be Solved by the Invention

However, the inventors studied this and found that with the art which is described in Patent Document 1, since a step is required for bringing a compound having a structure able to coordinate with a metal into contact with the surface of the resin layer, the production process is troublesome and the production costs end up rising. Further, when curing the resin composition described in Patent Document 2 to obtain a cured product and treating its surface to roughen it by an aqueous solution of a permanganate, it became clear that the roughness of the surface roughened surface was small, but the adhesion with the plating metal was insufficient.

An object of the present invention is to provide a curable resin composition able to give a cured product which is low in surface roughness when treated on its surface by an aqueous solution of a permanganate and which is excellent in adhesion with the conductor layer and in electrical characteristics and a cured product, surface treated cured product, and laminate which are obtained using the same.

### Means for Solving the Problems

The inventors engaged in intensive research to achieve the above object and as a result discovered that a cured product which is obtained using a curable resin composition which contains an alicyclic olefin polymer having polar groups, a curing agent, a hindered phenol compound, and a hindered amine compound has a small surface roughness when treated on its surface by an aqueous solution of a permanganate, is excellent in adhesion to a conductor layer, is high in peel strength, and is excellent in electrical characteristics as well and thereby completed the present invention.

That is, according to the present invention, there are provided:

[1] A curable resin composition comprised of an alicyclic olefin polymer (A) having polar groups, a curing agent (B) a hindered phenol compound (C), and a hindered amine compound (D),

[2] The curable resin composition as set forth in [1], wherein the polar groups of the alicyclic olefin polymer (A) are of at least one type selected from the group comprised of a carboxyl group, carboxylic anhydride group, and phenolic hydroxyl group,

[3] The curable resin composition as set forth in [1] or [2] wherein the curing agent (B) is a compound which has two or more functional groups in its molecule,

[4] The curable resin composition as set forth in any one of [1] to [3], wherein a ratio of the hindered phenol compound (C) and the hindered amine compound (D) is, in weight ratio of the compound (C)/compound (D) 1/0.05 to 1/25,

[5] A shaped article obtained by forming the curable resin composition as set forth in any of [1] to [4] into a sheet shape or a film shape,

[6] A cured article obtained by curing the curable resin composition as set forth in any one of [1] to [4] or the sheet-shaped or film-shaped shaped article as set forth in [5],

[7] A surface treated cured article obtained by roughening the surface of the cured article as set forth in [6] by an aqueous solution of a permanganate, then electrolessly plating the roughened surface,

[8] A laminate obtained by laminating a board which has a conductor layer on its surface and the cured article as set forth in [6] or the surface treated cured article as set forth in [7],

[9] A multilayer circuit board obtained by further forming a conductor layer on the layer comprised of the cured article or surface treated cured article of the laminate as set forth in [8], and

[10] An electronic device which is provided with the multilayer circuit board as set forth in [9].

### Effects of the Invention

According to the present invention, a curable resin composition ablet to give a cured product which is small in surface roughness when treated on its surface by an aqueous solution of a permanganate, is excellent in adhesion to a conductor layer, is high in peel strength, and is excellent in electrical characteristics as well and a cured product, surface treated cured product, and laminate which are obtained using the same are provided. In particular, when made a cured product and treated on its surface for roughening by an aqueous solution of a permanganate, the curable resin composition of the present invention has the property of being able to keep the surface roughness small even if the surface roughening treatment conditions change. For this reason, according to the curable resin composition of the present invention, it becomes possible to stably obtain a cured product with a small surface roughness without controlling the surface roughening treatment conditions with a high precision.

### DESCRIPTION OF EMBODIMENTS

The curable resin composition of the present invention contains an alicyclic olefin polymer (A) having polar groups, a curing agent (B), a hindered phenol compound (C), and a hindered amine compound (D).

(Alicyclic Olefin Polymer (A) Having Polar Groups)

As the alicyclic structure forming the alicyclic olefin polymer (A) having polar groups which is used in the present invention (below, suitably abbreviated as the “alicyclic olefin polymer (A)”), a cycloalkane structure, cycloalkene structure, etc. may be mentioned, but from the viewpoint of the mechanical strength, the heat resistance, etc., a cycloalkane structure is preferable. Further, as the alicyclic structure, a single ring, multiple ring, condensed multiple ring, bridged multiple ring, multiple ring of a combination of the same, etc. may be mentioned. The number of carbon atoms which form the alicyclic structure is not particularly limited, but is usually 4 to 30, preferably 5 to 20, more preferably 5 to 15 in range. If the number of carbon atoms which form the alicyclic structure is in this range, the characteristics of the mechanical strength, heat resistance, and shapeability are balanced to a high degree, so this is suitable. Further, the alicyclic olefin polymer (A) is usually thermoplastic, but can exhibit thermosettability by use combined with a curing agent.

The alicyclic structure of the alicyclic olefin polymer (A) is comprised of repeating units derived from olefins which have alicyclic structures formed by carbon atoms (alicyclic olefins) or monomer units which can be viewed as identical to such repeating units (below, for convenience, these together being referred to as “repeating units derived from alicyclic olefins”). The ratio of repeating units derived from alicyclic olefins in the alicyclic olefin polymer (A) is not particularly limited, but is usually 30 to 100 wt %, preferably 50 to 100 wt %, more preferably 70 to 100 wt %. If the ratio of repeating units derived from alicyclic olefins is excessively low, the heat resistance becomes inferior, so this is not preferable. The repeating units other than repeating units derived from alicyclic olefins are not particularly limited and may be suitably selected in accordance with the objective.

The polar groups which the alicyclic olefin polymer (A) has are not particularly limited, but an alcoholic hydroxyl group, phenolic hydroxyl group, carboxyl group, alkoxyl group, epoxy group, glycidyl group, oxycarbonyl group, carbonyl group, amino group, ester group, carboxylic anhydride group, sulfonic acid group, phosphoric acid group, etc. may be mentioned. Among these, a carboxyl group, carboxylic anhydride group, and phenolic hydroxyl group are preferable. Note that, the alicyclic olefin polymer (A) may have two or more types of polar groups. Further, the polar groups of the alicyclic olefin polymer (A) may be directly bonded with atoms forming the main chain of the polymer or may be bonded through a methylene group, oxy group, oxycarbonyloxyalkylene group, phenylene group, or other bivalent group. The polar groups may be bonded in the alicyclic olefin polymer (A) with repeating units derived from alicyclic olefins or may be bonded with repeating units other than such units. The content of the polar groups in the alicyclic olefin polymer (A) is not particularly limited, but is usually 5 to 60 mol %, preferably 10 to 50 mol %, with respect to the number of moles of all repeating units which form the alicyclic olefin polymer (A).

The alicyclic olefin polymer (A) which is used in the present invention can, for example, be obtained by the following methods. That is, it can be obtained by (1) the method of polymerizing an alicyclic olefin having polar groups with another monomer which is used in accordance with need, (2) the method of copolymerizing an alicyclic olefin which does not have polar groups with a monomer which has polar groups, (3) the method of polymerizing an aromatic olefin having polar groups with another monomer which is used in accordance with need and hydrogenating the aromatic ring part of the polymer which is obtained by the same, (4) the method of copolymerizing an aromatic olefin which does not have polar groups with a monomer having polar groups and hydrogenating the aromatic ring part of the polymer which is obtained by the same, (5) the method of introducing a compound having polar groups to an alicyclic olefin polymer which does not have polar groups by a denaturing reaction, and (6) the method of converting the polar groups of an alicyclic olefin polymer having polar groups which is obtained like in the above (1) to (5) (for example, carboxylic acid ester groups etc.) to other polar groups (for example, carboxyl groups) by, for example, hydrolysis. Among these, polymers which are obtained by the method of the above-mentioned (1) are suitable.

The polymerization method which gives the alicyclic olefin polymer (A) which is used in the present invention is ring-opening polymerization or addition polymerization, but in the case of ring-opening polymerization, it is preferable to hydrogenate the obtained ring-opening polymer.

As specific examples of alicyclic olefins having polar groups which can be used as monomers having polar groups, 5-hydroxycarbonyl bicyclo[2.2.1]hept-2-ene, 5-methyl-5-hydroxycarbonylbicyclo[2.2.1]hept-2-ene, 5-carboxymethyl-5-hydroxycarbonylbicyclo[2.2.1]hept-2-ene, 9-hydroxycarbonyltetracyclo[6.2.1.1^{3,6}.0^{2,7}]dodeca-4-ene, 9-methyl-9-hydroxycarbonyltetracyclo[6.2.1.1^{3,6}.0^{2,7}]dodeca-4-ene, 9-carboxymethyl-9-hydroxycarbonyltetracyclo[6.2.1.1^{3,6}.0^{2,7}]dodeca-4-ene, 5-exo-6-endo-dihydroxycarbonylbicyclo[2.2.1]hept-2-ene, 9-exo-10-endo-dihydroxycarbonyltetracyclo[6.2.1.1^{3,6}.0^{2,7}]dodeca-4-ene, and other alicyclic olefins having carboxyl groups; bicyclo[2.2.1]hept-2-ene-5,6-dicarboxylic anhydride, tetracyclo[6.2.1.1^{3,6}.0^{2,7}]dodeca-4-ene-9,10-dicarboxylic anhydride, hexacyclo[10.2.1.1^{3,10}. 1^{5,8}.0^{2,11}.0^{4,9}]anhydride, and other alicyclic olefins having carboxylic anhydride groups; 9-methyl-9-methoxycarbonyltetracyclo[6.2.1.1^{3,6}.0^{2,7}]dodeca-4-ene, 5-methoxycarbonyl-bicyclo[2.2.1]hept-2-ene, 5-methyl-5-methoxycarbonyl-bicyclo[2.2.1]hept-2-ene, and other alicyclic olefins having carboxylic acid ester groups; (5-(4-hydroxyphenyl)bicyclo [2.2.1]hept-2-ene, 9-(4-hydroxyphenyl)tetracyclo[6.2.1.1^{3,6}.0^{2,7}]dodeca-4-ene, N-(4-hydroxyphenyl)bicyclo[2.2.1]hept-5-ene-2,3-dicarboxylmide, and other alicyclic olefins having phenolic hydroxyl groups; etc. may be mentioned. These may be used alone as single types or may be used as two or more types.

As specific examples of alicyclic olefins which do not have polar groups, bicyclo[2.2.1]hept-2-ene (common name: norbornene), 5-ethyl-bicyclo[2.2.1]hept-2-ene, 5-butyl-bicyclo[2.2.1]hept-2-ene, 5-ethylidene-bicyclo[2.2.1]hept-2-ene, 5-methylidene-bicyclo[2.2.1]hept-2-ene, 5-vinyl-bicyclo[2.2.1]hept-2-ene, tricyclo[5.2.1.0^{2,6}]deca-3,8-diene (common name: dicyclopentadiene), tetracyclo[6.2.1.1^{3,6}.0^{2,7}]dodeca-4-ene (common name: tetracyclododecene), 9-methyl-tetracyclo[6.2.1.1^{3,6}.0^{2,7}]dodeca-4-ene, 9-ethyl-tetracyclo[6.2.1.1^{3,6}.0^{2,7}]dodeca-4-ene, 9-methylidene-tetracyclo[6.2.1.1^{3,6}.0^{2,7}]dodeca-4-ene, 9-ethylidene-tetracyclo[6.2.1.1^{3,6}.0^{2,7}]dodeca-4-ene, 9-methoxycarbonyl-tetracyclo[6.2.1.1^{3,6}.0^{2,7}]dodeca-4-ene, 9-vinyl-tetracyclo[6.2.1.1^{3,6}.0^{2,7}]dodeca-4-ene, 9-propenyl-tetracyclo[6.2.1.1^{3,6}.0^{2,7}]dodeca-4-ene, 9-phenyl-tetracyclo[6.2.1.1^{3,6}.0^{2,7}]dodeca-4-ene, tetracyclo[9.2.1.0^{2,10}.0^{3,8}] tetradeca-3,5,7,12-tetraene, cyclopentene, cyclopentadiene, etc. may be mentioned. These may be used alone as single types or may be used as two or more types.

As examples of aromatic olefins which do not have polar groups, styrene, α-methylstyrene, divinylbenzene, etc. may be mentioned. These may be used alone as single types or may be used as two or more types.

As monomers having polar groups, other than alicyclic olefins having polar groups, which can be copolymerized with alicyclic olefins or aromatic olefins, ethylenically unsaturated compounds having polar groups may be mentioned. As specific examples, acrylic acid, methacrylic acid, α-ethylacrylic acid, 2-hydroxyethyl(meth)acrylic acid, maleic acid, furnaric acid, itaconic acid, and other unsaturated carboxylic acid compounds; maleic anhydride, butenyl succinic anhydride, tetrahydrophthalic anhydride, citraconic anhydride, and other unsaturated carboxylic anhydrides; etc. may be mentioned. These may be used alone as single types or may be used as two or more types.

As monomers which do not have polar groups, other than alicyclic olefins, which can be copolymerized with alicyclic olefins or aromatic olefins, ethylenically unsaturated compounds which do not have polar groups may be mentioned. As specific examples, ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, 1-eicosene, and other C₂ to C₂₀ ethylenes or α-olefins; 1,4-hexadiene, 4-methyl-1,4-hexadiene, 5-methyl-1,4-hexadiene, 1,7-octadiene, and other nonconjugated dienes; etc. may be mentioned. These may be used alone as single types or may be used as two or more types.

The molecular weight of the alicyclic olefin polymer (A) which is used in the present invention is not particularly limited, but the weight average molecular weight converted to polystyrene which is measured by gel permeation chromatography using tetrahydrofuran as a solvent is preferably 500 to 1,000,000 in range, more preferably 1,000 to 500,000 in range, and particularly preferably 5,000 to 300,000 in range. If the weight average molecular weight is too small, the mechanical strength of the cured product which is obtained by curing the curable resin composition falls, while if it is too large, the workability when forming the composition into a sheet shape or film shape to obtain a shaped article tends to deteriorate.

As the polymerization catalyst when obtaining the alicyclic olefin polymer (A) which is used in the present invention by the ring-opening polymerization method, it is possible to use a conventionally known metathesis polymerization catalyst. As the metathesis polymerization catalyst, a transition metal compound which contains Mo, W, Nb, Ta, Ru, or other atoms may be illustrated. Among these, a compound which contains Mo, W, or Ru is high in polymerization activity and therefore is preferable. As specific examples of a particularly preferable metathesis polymerization catalyst, (1) a catalyst which has a molybdenum or tungsten compound which has a halogen group, imide group, alkoxy group, allyloxy group, or carbonyl group as a ligand as a main catalyst and which has an organometal compound as a second ingredient or (2) a metal carbene complex catalyst which has Ru as a central metal may be mentioned.

As examples of the compound which is used as the main catalyst in the catalyst of the above (1), MoCl₅, MoBr₅, and other halogenated molybdenum compounds or WCl₆, WOCl₄, tungsten (phenylimide)tetrachloride.diethyl ether, and other halogenated tungsten compounds may be mentioned. Further, in the catalyst of the above (1), as the organometal compound which is used as the second ingredient, organometal compounds of the Group I, Group II, Group XII, Group XIII, or Group XIV of the Periodic Table may be mentioned. Among these, organolithium compounds, organomagnesium compounds, organozinc compounds, organoaluminum compounds, and organotin compounds are preferable and organolithium compounds, organoaluminum compounds, and organotin compounds are particularly preferable. As the organolithium compounds, n-butyllithium, methyllithium, phenyllithium, neopentyllithium, neophyllithium, etc. may be mentioned. As the organomagnesium compounds, butylethylmagnesium, butyloctylmagnesium, dihexylmagnesium, ethylmagnesium chloride, n-butyl magnesium chloride, allylmagnesium bromide, neopentylmagnesium chloride, neophylmagnesium chloride, etc. may be mentioned. As the organozinc compounds, idimethylz inc, diethyl zinc, diphenylzinc, etc. may be mentioned. As the organoaluminum compounds, trimethylaluminum, triethylaluminum, triisobutylaluminum, diethylaluminum chloride, ethylaluminum sesquichloride, ethylaluminum dichloride, diethylaluminum ethoxide, ethylaluminum diethoxide, etc. may be mentioned. Furthermore, the aluminoxane compounds which are obtained by reaction of these organoaluminum compounds and water may also be used. As the organotin compounds, tetramethyltin, tetra(n-butyl) tin, tetraphenyltin, etc. may be mentioned. The amount of these organometal compounds differs depending on the organometal compound which is used, but is preferably 0.1 to 10,000 time mol in molar ratio with respect to the central metal of the main catalyst, more preferably 0.2 to 5,000 time mol, particularly preferably 0.5 to 2,000 time mol.

Further, as the metal carbene complex catalyst having Ru as the central metal in the above (2), (1,3-dimesityl-imidazolidin-2-ylidene) (tricyclohexyl-phosphine)benzylideneruthenium dichloride, bis(tricyclohexylphosphine)benzylideneruthenium dichloride, tricyclohexylphosphine-[1,3-bis(2,4,6-trimethylphenyl)-4,5-dibromoimidazol-2-ylidene]-[benzylidene] ruthenium dichloride, 4-acetoxybenzylidene (dichloro) (4,5-dibromo-1,3-dimesityl-4-imidazolin-2-ylidene) (tricyclohexylphosphine) ruthenium etc. may be mentioned.

The ratio of use of the metathesis polymerization catalyst is, by molar ratio with respect to the monomer which is used for the polymerization (transition metal in metathesis polymerization catalyst:monomer), usually 1:100 to 1:2,000,000 in range, preferably 1:200 to 1:1,000,000 in range. If the amount of the catalyst is too large, removal of the catalyst becomes difficult, while if too small, a sufficient polymerization activity is liable to not be obtained.

The polymerization reaction is usually performed in an organic solvent. The organic solvent which is used is not particularly limited so long as the polymer dissolves or disperses under predetermined conditions and the solvent does not affect the polymerization, but one which is generally used industrially is preferable. As specific examples of the organic solvent, pentane, hexane, heptane, and other aliphatic hydrocarbons; cyclopentane, cyclohexane, methylcyclohexane, dimethylcyclohexane, trimethylcyclohexane, ethylcyclohexane, diethylcyclohexane, decahydronaphthalene, bicycloheptane, tricyclodecane, hexahydroindenecyclohexane, cyclooctane, and other alicyclic hydrocarbons; benzene, toluene, xylene, and other aromatic hydrocarbons; dichloromethane, chloroform, 1,2-dichloroethane, and other halogen-based aliphatic hydrocarbons; chlorobenzene, dichlorobenzene, and other halogen-based aromatic hydrocarbons; nitromethane, nitrobenzene, acetonitrile, and other nitrogen-containing hydrocarbon-based solvents; diethylether, tetrahydrofuran, and other ether-based solvents; anisole, phenetol, and other aromatic ether-based solvents; etc. may be mentioned. Among these as well, the industrially generally used aromatic hydrocarbon-based solvents or aliphatic hydrocarbon-based solvents, alicyclic hydrocarbon-based solvents, ether-based solvents, and aromatic ether-based solvents are preferable.

The amount of the organic solvent used is preferably an amount giving a concentration of the monomer in the polymerization solution of 1 to 50 wt %, more preferably 2 to 45 wt %, particularly preferably 3 to 40 wt %. If the concentration of the monomer is less than 1 wt %, the productivity deteriorates, while if over 50 wt %, the viscosity of the solution after polymerization becomes too high and sometimes the subsequent hydrogenation reaction becomes difficult.

The polymerization reaction is started by mixing the monomer which is used for the polymerization and a metathesis polymerization catalyst. As the method of mixing these, the metathesis polymerization catalyst solution may be added to the monomer solution or the reverse. When the metathesis polymerization catalyst which is used is a mixed catalyst comprised of a main catalyst of a transition metal compound and a second ingredient of an organometal compound, the reaction solution of the mixed catalyst may be added to the monomer solution or the reverse. Further, a transition metal compound solution may be added to a mixed solution of the monomer and the organometal compound or the reverse. Furthermore, the organometal compound may be added to the mixed solution of the monomer and the transition metal compound or the reverse.

The polymerization temperature is not particularly limited, but is usually −30° C. to 200° C., preferably 0° C. to 180° C. The polymerization time is not particularly limited, but is usually 1 minute to 100 hours.

As the method for adjusting the molecular weight of the obtained alicyclic olefin polymer, it is possible to mention the method of adding a suitable amount of a vinyl compound or diene compound. The vinyl compound which is used for adjustment of the molecular weight is not particularly limited so long as an organic compound having vinyl groups, but 1-butene, 1-pentene, 1-hexene, 1-octene, and other α-olefins; styrene, vinyl toluene, and other styrenes; ethylvinyl ether, i-butylvinyl ether, allylglycidyl ether, and other ethers; allylchloride and other halogen-containing vinyl compounds; allyl acetate, allyl alcohol, glycidyl methacrylate, and other oxygen-containing vinyl compounds, acrylamide and other nitrogen-containing vinyl compounds, etc. may be mentioned. As the diene compound which is used for the adjustment of the molecular weight, 1,4-pentadiene, 1,4-hexadiene, 1,5-hexadiene, 1,6-heptadiene, 2-methyl-1,4-pentadiene, 2,5-dimethyl-1,5-hexadiene, and other nonconjugated dienes or 1,3-butadiene, 2-methyl-1,3-butadiene, 2,3-dimethyl-1,3-butadiene, 1,3-pentadiene, 1,3-hexadiene, and other conjugated dienes may be mentioned. The amount of addition of the vinyl compound or diene compound may be arbitrarily selected in accordance with the molecular weight which is targeted from between 0.1 to 10 mol % with respect to the monomer which is used for the polymerization.

As the polymerization catalyst in the case where the alicyclic olefin polymer (A) which is used in the present invention is obtained by the addition polymerization method, for example, a catalyst which is comprised of a titanium, zirconium, or vanadium compound and an organoaluminum compound is preferably used. These polymerization catalysts may be used alone or in combinations of two or more types. The amount of the polymerization catalyst is, by molar ratio of “the metal compound in the polymerization catalyst: the monomer which is used for the polymerization”, usually 1:100 to 1:2,000,000 in range.

When using a hydrogenate of a ring-opening polymer as the alicyclic olefin polymer (A) which is used in the present invention, the hydrogenation of the ring-opening polymer is usually performed using a hydrogenation catalyst. The hydrogenation catalyst is not particularly limited. One which is generally used when hydrogenating an olefin compound may be suitably employed. As specific examples of the hydrogenation catalyst, for example, Ziegler-type catalysts comprised of combinations of cobalt acetate and triethylaluminum, nickel acetylacetonate and triisobutylaluminum, titanocene dichloride and n-butyllithium, zirconocene dichloride and sec-butyllithium, tetrabutoxytitanate and dimethylmagnesium, and other such transition metal compounds and alkali metal compounds; dichlorotris(triphenylphosphine) rhodium, and the catalysts described in Japanese Patent Publication No. 7-2929, Japanese Patent Publication No. 7-149823, Japanese Patent Publication No. 11-209460, Japanese Patent Publication No. 11-158256, Japanese Patent Publication No. 11-193323, Japanese Patent Publication No. 11-209460, etc., for example, bis(tricyclohexylphosphine)benzylidyne ruthenium (IV) dichloride and other precious metal complex catalysts comprised of ruthenium compounds; and other homogeneous catalysts may be mentioned. Further, heterogeneous catalysts comprised of nickel, palladium, platinum, rhodium, ruthenium, and other metals carried on carbon, silica, diatomite, alumina, titanium oxide, and other carriers, for example, nickel/silica, nickel/diatomite, nickel/alumina, palladium/carbon, palladium/silica, palladium/diatomite, palladium/alumina, etc. may be used. Further, the above-mentioned metathesis polymerization catalyst may also be used as is as a hydrogenation catalyst.

The hydrogenation reaction is usually performed in an organic solvent. The organic solvent can be suitably selected by the solubility of the hydrogenate which is produced. It is possible to use an organic solvent similar to the organic solvent which is used for the above-mentioned polymerization reaction. Therefore, after the polymerization reaction, it is also possible to not switch the organic solvent, but to continue to add the hydrogenation catalyst to cause a reaction. Furthermore, among the organic solvents which are used in the above-mentioned polymerization reaction, from the viewpoint of not reacting at the time of a hydrogenation reaction, an aromatic hydrocarbon-based solvent or aliphatic hydrocarbon-based solvent, alicyclic hydrocarbon-based solvent, ether-based solvent, or aromatic ether-based solvent is preferable, while an aromatic ether-based solvent is more preferable.

The hydrogenation reaction conditions may be suitably selected in accordance with the type of the hydrogenation catalyst which is used. The reaction temperature is usually −20 to 250° C., preferably −10 to 220° C., more preferably 0 to 200° C. If less than −20° C., the reaction speed becomes slower, while conversely if over 250° C., secondary reactions more easily occur. The pressure of the hydrogen is usually 0.01 to 10.0 MPa, preferably 0.05 to 8.0 MPa. If the hydrogen pressure is less than 0.01 MPa, the hydrogenation speed becomes slow, while if it is over 10.0 MPa, a high pressure resistance reaction apparatus becomes necessary.

The time of the hydrogenation reaction is suitably selected for controlling the hydrogenation rate. The reaction time is usually 0.1 to 50 hours in range. Among the carbon-carbon double bonds of the main chain in the polymer, 50% or more, preferably 70% or more, more preferably 80% or more, particularly preferably 90% or more, may be hydrogenated.

After the hydrogenation reaction, treatment to remove the catalyst which was used for the hydrogenation reaction may be performed. The method of removal of the catalyst is not particularly limited. Centrifugation, filtration, and other methods may be mentioned. Furthermore, water or alcohol or other catalyst deactivators may be added or activated clay, alumina, diatomite, or other adsorbents may be added so as to promote removal of the catalyst.

For the alicyclic olefin polymer (A) which is used in the present invention it is possible to use the solution after the polymerization or hydrogenation reaction as is as the polymerization solution or use it after removal of the solvent, but since the dissolution or dispersion of the additives becomes good when preparation of the resin composition and the process can be streamlined, use as the polymerization solution is preferable.

The amount of the alicyclic olefin polymer (A) in the curable resin composition of the present invention is usually 20 to 90 wt %, preferably 30 to 80 wt %, more preferably 40 to 70 wt %.

(Curing Agent (B))

The curing agent (B) which is used in the present invention is not particularly limited so long as able to make the alicyclic olefin polymer (A) have a cross-linked structure by heating. It is possible to use a general curing agent which is blended into the curable resin composition for formation of an electrical insulating film. As the curing agent (B), it is preferable to use as a curing agent a compound which has two or more functional groups able to react with the polar groups of the used alicyclic olefin polymer (A) to form bonds.

For example, as the curing agent which is suitably used when using as the alicyclic olefin polymer (A) an alicyclic olefin polymer (A) which has carboxyl groups or carboxylic anhydride groups or phenolic hydroxyl groups, a polyvalnet epoxy compound, polyvalnet isocyanate compound, polyvalnet amine compound, polyvalnet hydrazide compound, aziridine compound, basic metal oxide, organometal halide, etc. may be mentioned. These may be used alone as single types or may be used as two or more types. Further, by jointly using these compounds and peroxides, it is possible to use them as a curing agent.

As the polyvalnet epoxy compound, for example, a phenol novolac type epoxy compound, cresol novolac type epoxy compound, cresol type epoxy compound, bisphenol A type epoxy compound, bisphenol F type epoxy compound, hydrogenated bisphenol A type epoxy compound, and other glycidyl ether type epoxy compounds; an alicyclic epoxy compound, glycidyl ester type epoxy compound, glycidyl amine type epoxy compound, fluorene-based epoxy compound, polyfunctional epoxy compound, isocyanulate type epoxy compound, phosphorus-containing epoxy compound, and other polyvalnet epoxy compounds; and other compounds which have two or more epoxy groups in its molecule may be mentioned. These may be used alone as single types or may be used as two or more types.

As the polyvalnet isocyanate compound, C₆ to C₂₄ diisocyanates and triisocyanates are preferable. As examples of diisocyanates, 2,4-tolylene diisocyanate, 2,6-tolylene diisocyanate, 4,4′-diphenylmethane diisocyanate, hexamethylene diisocyanate, p-phenylene diisocyanate, etc. may be mentioned. As examples of triisocyanates, 1,3,6-hexamethylene diisocyanate, 1,6,11-undecane triisocyanate, bicycloheptane triisocyanate, etc. may be mentioned. These may be used alone as single types or may be used as two or more types.

As the polyvalent amine compound, a two or more amino group-containing C₄ to C₃₀ aliphatic polyvalent amine compounds, aromatic polyvalent amine compounds, etc. may be mentioned. One such as a guanidine compound which has nonconjugated nitrogen-carbon double bonds is not included. As the aliphatic polyvalent amine compounds, hexamethylenediamine, N,N′-dicinnamylidene-1,6-hexanediamine etc. may be mentioned. As the aromatic polyvalent amine compounds, 4,4′-methylenedianiline, m-phenylenediamine, 4,4′-diamino-diphenylether, 4′-(m-phenylenediisopropylidene)dianiline, 4,4′-(p-phenylenediisopropylidene)dianiline, 2,2′-bis[4-(4-aminophenoxy)phenyl]propane, 1,3,5-benzenetriamine, etc. may be mentioned. These may be used alone as single types or may be used as two or more types.

As examples of a polyvalent hydrazide compound, dihydrazide isophthalate, dihydrazide terephthalate, dihydrazide 2,6-naphthalene dicarboxylate, dihydrazide maleate, dihydrazide itaconate, dihydrazide trimellitate, dihydrazide 1,3,5-benzenetricarboxylate, dihydrazide pyromellitate, etc. may be mentioned. These may be used alone as single types or may be used as two or more types.

As the aziridine compound, tris-2,4,6-(1-aziridinyl)-1,3,5-triazine, tris[1-(2-methyl)aziridinyl]phosphinoxide, hexa[1-(2-methyl)aziridinyl]triphosphatriazine, etc. may be mentioned. These may be used alone as single types or may be used as two or more types.

Among the above-mentioned curing agents, from the viewpoint of that the reactivity with the polar groups of the alicyclic olefin polymer (A) is moderate and the ease of handling of the curable resin composition, a polyvalent epoxy compound is preferably used while a glycidyl ether type or alicyclic condensation type polyvalent epoxy compound is particularly preferably used.

The amount of the curing agent (B) is usually 1 to 60 wt % in the curable resin composition of the present invention, preferably 2 to 40 wt %, more preferably 3 to 30 wt % in range. By making the amount of the curing agent the above range, it is possible to make the cured product which is obtained by curing the curable resin composition excellent in mechanical strength and electrical characteristics, so this is preferable.

(Hindered Phenol Compound (C))

The hindered phenol compound (C) is a phenol compound which has a hydroxyl group and at least one hindered structure not having a hydrogen atom at the carbon atom of the p-position of the hydroxyl group in its molecule.

As specific examples of the hindered phenol compound (C), 1,1,3-tris-(2-methyl-4-hydroxy-5-tert-butylphenyl)butane, 4,4′-butylidenebis-(3-methyl-6-tert-butylphenol), 2,2-thiobis(4-methyl-6-tert-butylphenol), n-octadecyl-3-(4 ‘-hydroxy-3’, 5′-di-tert-butyl-phenyl) propionate, tetrakis-[methylene-3-(3′,5′-di-tert-butyl-4′-hydroxyphenyl)propionate], ethane, pentaerythritol-tetrakis[3-(3,5-di-tert-butyl-4-hydroxyphenyl)propionate], triethyleneglycol-bis[3-(3-tert-butyl-5-methyl-4-hydroxyphenyl)propionate], 1,6-hexanej ol-bis[3-(3,5-di-tert-butyl-4-hydroxyphenyl)propionate], 2,4-bis(n-octylthio)-6-(4-hydroxy-3,5-di-tert-butylanilino)-1,3,5-triazine, tris-(3,5-di-tert-butyl-4-hydroxybenzyl)-isocyanulate, 2,2-thio-diethylenebis[3-(3,5-di-tert-butyl-4-hydroxyphenyl)propionate], N,N′-hexamethylenebis(3,5-di-tert-butyl-4-hydroxy-hydrocinnamamide, 2,4-bis[(octylthio)methyl]-o-cresol, calcium bis(ethyl 3,5-di-tert-butyl-4-hydroxybenzylphosphonate), 3,5-di-tert-butyl-4-hydroxybenzyl-phosphonate-diethyl ester, tetrakis[methylene (3,5-di-tert-butyl-4-hydroxyhydrocinnamate)]methane, octadecyl-3-(3,5-di-tert-butyl-4-hydroxyphenyl)propionic acid ester, hindered.bisphenol, etc. may be mentioned.

The amount of the hindered phenol compound (C) is not particularly limited, but is usually 0.05 to 5 wt % in the curable resin composition of the present invention, preferably 0.1 to 3 wt %, more preferably 0.15 to 2 wt % in range. By making the amount of the hindered phenol compound (C) the above range, it is possible to make the cured product which is obtained by curing the curable resin composition excellent in mechanical strength.

(Hindered Amine Compound (D))

The hindered amine compound (D) is an amine compound which has at least one of the following structures in its molecule. The number of the structures in the hindered amine compound (D) is not particularly limited, but is usually at least one, preferably at least two.

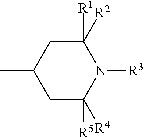

[where, R¹, R², R⁴, and R⁵ are the same or different from each other and indicate a C₁ to C₁₀ alkyl group, C₆ to C₂₀ aryl group, or C₇ to C₂₀ aralkyl group, and R³ indicates a hydrogen atom, C₁ to C₁₀ alkyl group, C₆ to C₂₀ aryl group, or C₇ to C₂₀ aralkyl group]

As specific examples of the hindered amine compound (D), bis(2,2,6,6,-tetramethyl-4-piperidyl)sebacate, bis(1,2,2,6,6-pentamethyl-4-piperidyl)sebacate, 1[2-{3-(3,5-di-tert-butyl-4-hydroxyphenyl)propionyloxy}ethyl]-4-{3-(3,5-di-tert-butyl-4-hydroxyphenyl)propionyloxy}-2,2,6,6,-tetramethylpiperidine, 8-benzyl-7,7,9,9-tetramethyl-3-octyl-1,2,3-triazaspiro[4,5]undecane-2,4-dione, 4-benzyloxy-2,2,6,6-tetramethylpiperidine, dimethyl-2-(2-hydroxyethyl)-4-hydroxy-2,2,6,6-tetramethylpiperidine succinate polycondensate, poly[[6-(1,1,3,3-tetramethylbutyl)imino-1,3,5-triazin-2,4-diyl][(2,2,6,6-tetramethyl-4-piperidyl)imino]hexamethylene[[2,2,6,6-tetramethyl-4-piperidyl)imino]], poly[(6-morpholino-s-triazin-2,4-diyl)[2,2,6,6-tetramethyl-4-piperidyl)imino]-hexamethylene[(2,2,6,6-tetramethyl-4-piperidyl)imino]], 2-(3,5-di-tert-butyl-4-hydroxybenzyl)-2-n-butylmalonate bis(1,2,2,6,6-pentamethyl-4-piperidyl), tetrakis(1,2,2,6,6-pentamethyl-4-piperidyl)1,2,3,4-butanetetracarboxylate, tetrakis(2,2,6,6-tetramethyl-4-piperidyl)1,2,3,4-butanetetracarboxylate, a condensate of 1,2,3,4-butanetetracarboxylic acid, 1,2,2,6,6-pentamethyl-4-piperidinol, and tridecyl alcohol, a condensate of 1,2,3,4-butanetetracarboxcylic acid, 2,2,6,6-tetramethyl-4-piperidinol, and tridecyl alcohol, a condensate of 1,2,3,4-butanetetracarboxylic acid, 1,2,2,6,6-pentamethyl-4-piperidinol, and β,β,β′,β′-tetramethyl-3,9-(2,4,8,10-tetraoxaspiro[5,5]undecane)diethanol, a condensate of N,N′-bis(3-aminopropyl)ethylenediamine and 2,4-bis[N-butyl-N-(1,2,2,6,6-pentamethyl-4-piperidyl)amino]-6-chloro-1,3,5-triazine, 1,2,2,6,6-tetramethyl-4-piperidyl-methacrylate, 2,2,6,6-tetramethyl-4-piperidyl-methacrylate, methyl-3-[3-tert-butyl-5-(2H-benzotriazol-2-yl)-4-hydroxyphenyl]propionate-polyethyleneglycol etc. may be mentioned.

By combining and mixing a hindered phenol compound (C) and hindered amine compound (D), the curable resin composition of the present invention has the property of being able to reduce the surface roughness when treating a cured product which is obtained for surface roughening using an aqueous solution of a permanganate and further of being able to maintain the surface roughened cured product small in surface roughness even when the surface roughening conditions change. That is, according to the present invention, by combining and mixing the hindered phenol compound (C) and the hindered amine compound (D) in the curable resin composition, it is possible to stably provide a cured product with a small surface roughness without precisely control the surface roughening conditions.

The amount of hindered amine compound (D) is not particularly limited, but is usually 0.05 to 5 wt % in the curable resin composition of the present invention, preferably 0.1 to 3 wt %, more preferably 0.15 to 2 wt % in range. By making the amount of the hindered amine compound (D) the above range, it is possible to make the cured product which is obtained by curing the curable resin composition excellent in mechanical strength.

Further, in the curable resin composition of the present invention, the ratio of the above-mentioned hindered phenol compound (C) and hindered amine compound (D) is, by weight ratio of the “the compound (C)/the compound (D)”, preferably 1/0.05 to 1/25, more preferably 1/0.1 to 1/10, furthermore preferably 1/0.25 to 1/5. If the ratio of the hindered phenol compound (C) and the hindered amine compound (D) is outside of the above range, sometimes the effect due to combining and mixing these ends up becoming smaller.

Further, the curable resin composition of the present invention may contain, in addition to the above ingredients, a curing accelerator or curing aid. As the curing accelerator, a general curing accelerator which is mixed into a curable resin composition for formation of an electrical insulating film may be used, but when using a curing agent comprised of a polyvalent epoxy compound, a tertiary amine-based compound (except hindered amine compound (D)) or boron trifluoride complex compound etc. is suitably used as the curing accelerator. Among these as well, if using a tertiary amine-based compound, the obtained cured product is high in effect of improvement of the insulation resistance, heat resistance, and chemical resistance, so this is preferable.

As specific examples of the tertiary amine-based compounds, for example, benzyldimethylamine, triethanolamine, triethylamine, tributylamine, tribenzylamine, dimethylformamide, and other chain tertiary amine compounds; pyrrazoles, pyridines, pyradines, pyrimidines, indazoles, quinolines, isoquinolines, imidazoles, triazoles, and other compounds may be mentioned. Among these, imidazoles, in particular substituted imidazole compounds which have substituents, are preferable.

As specific examples of substituted imidazole compounds, 2-ethylimidazole, 2-ethyl-4-methylimidazole, bis-2-ethyl-4-methylimidazole, 1-methyl-2-ethylimidazole, 2-isopropylimidazole, 2,4-dimethylimidazole, 2-heptadecyl-imidazole, and other alkyl substituted imidazole compounds; 2-phenylimidazole, 2-phenyl-4-methylimidazole, 1-benzyl-2-methylimidazole, 1-benzyl-2-ethyl-imidazole, 1-benzyl-2-phenylimidazole, benzimidazole, 2-ethyl-4-methyl-1-(2′-cyanoethyl)imidazole, 2-ethyl-4-methyl-1-[2′-(3,5″-diaminotriazinyl)ethyl]imidazole, and other imidazole compounds substituted by aryl groups, aralkyl groups or other hydrocarbon groups containing ring structures etc. may be mentioned. Among these, the compatibility with the alicyclic olefin polymer (A) is excellent, so an imidazole compound which has a substituent containing a ring structure is preferable. Particularly, 1-benzyl-2-phenylimidazole is more preferable.

These curing accelerators may be used alone or as two or more types in combination. The amount of curing accelerator may be suitably selected in accordance with the purpose of use, but is usually 0.001 to 30 parts by weight with respect to 100 parts by weight of the alicyclic olefin polymer (A), preferably 0.01 to 10 parts by weight, more preferably 0.03 to 5 parts by weight.

As the curing aid, a general curing aid which is mixed into a curable resin composition for formation of an electrical insulating film may be used, but as specific examples, quinonedioxime, benzoquinonedioxime, p-nitrosophenol, and other oxime-nitroso-based curing aids; N,N-m-phenylene bismaleimide and other maleimide-based curing aids; diallyl phthalate, triallyl cyanulate, triallyl isocyanulate, and other allyl-based curing aids; ethyleneglycol dimethacrylate, trimethylolpropane trimethacrylate, and other methacrylate-based curing aids; vinyltoluene, ethylvinylbenzene, divinylbenzene, and other vinyl-based curing aids; etc. may be mentioned. These curing aids may be used alone or as two or more types in combination. The amount of curing aid is usually 1 to 1000 parts by weight with respect to 100 parts by weight of the curing agent (B), preferably 10 to 500 parts by weight in range.

Further, the curable resin composition of the present invention may, in accordance with need, have a rubbery polymer or another thermoplastic resin other than the above alicyclic olefin polymer (A) mixed into it. As the rubbery polymer, a polymer which has a glass transition temperature of ordinary temperature (25° C.) or less including a general rubbery polymer and thermoplastic elastomer. By mixing into the curable resin composition of the present invention a rubbery polymer or other thermoplastic resin, it is possible to improve the flexibility of the obtained cured product. The Mooney viscosity (ML₁₊₄, 100° C.) of the used rubbery polymer may be suitably selected, but is usually 5 to 200.

As specific examples of the rubbery polymer, an ethylene-α-olefin-based rubbery polymer; an ethylene-α-olefin-polyene copolymer rubber; ethylene-methyl methacrylate, ethylene-butyl acrylate, and other copolymers of ethylene and an unsaturated carboxylic acid ester; ethylene-vinyl acetate and other copolymers of ethylene and vinyl aliphatic acid salts; polymers of ethyl acrylate, butyl acrylate, hexyl acrylate, 2-ethylhexyl acrylate, lauryl acrylate, and other acrylic acid alkyl esters; polybutadiene, polyisoprene, a random copolymer of styrene-butadiene or styrene-isoprene, acrylonitrile-butadiene copolymer, butadiene-isoprene copolymer, butadiene-(meth)acrylic acid alkyl ester copolymer, butadiene-(meth)acrylic acid alkyl ester-acrylonitrile copolymer, butadiene-(meth)acrylic acid alkyl ester-acrylonitrile-styrene copolymer, and other diene-based rubber; epoxylated polybutadiene and other modified diene-based rubber; butylenes-isoprene copolymer; etc. may be mentioned.

As specific examples of the thermoplastic elastomer, a styrene-butadiene block copolymer, hydrogenated styrene-butadiene block copolymer, styrene-isoprene block copolymer, hydrogenated styrene-isoprene block copolymer, and other aromatic vinyl-conjugated diene-based block copolymers, low crystallinity polybutadiene resin, ethylene-propylene elastomer, styrene graftef ethylene-propylene elastomer, thermoplastic polyester elastomer, ethylene-based ionomer resin, etc. may be mentioned. Among these thermoplastic elastomers, a hydrogenated styrene-butadiene block copolymer and hydrogenated styrene-isoprene block copolymer are preferable. For example, the ones described in Japanese Patent Publication No. 2-133406, Japanese Patent Publication No. 2-305814, Japanese Patent Publication No. 3-72512, Japanese Patent Publication No. 3-74409, etc. are preferably used.

As other thermoplastic resins, for example, low density polyethylene, high density polyethylene, linear low density polyethylene, ultralow density polyethylene, ethylene-ethyl acrylate copolymer, ethylene-vinyl acetate copolymer, polystyrene, polyphenylene sulfide, polyphenylene ether, polyamide, polyester, polycarbonate, cellulose triacetate, etc. may be mentioned.

The above-mentioned rubbery polymer or other thermoplastic resin may be used alone or in two or more types combined. The amount is suitably selected in a range not detracting from the object of the present invention, but is preferably made an amount of 30 parts by weight or less with respect to 100 parts by weight of the alicyclic olefin polymer (A).

The curable resin composition of the present invention may have blended in it, for the purpose of improving the flame retardance at the time of forming a cured product, for example, a halogen-based flame retardant or phosphoric acid ester-based flame retardant or other general flame retardant which is blended into a curable resin composition for formation of an electrical insulating film. The amount in the case of blending a flame retardant in the curable resin composition of the present invention is preferably 100 parts by weight or less with respect to 100 parts by weight of the alicyclic olefin polymer (A), more preferably 60 parts by weight or less.

Further, the curable resin composition of the present invention may contain arbitrary inorganic filler or a polymer which can dissolve in an aqueous solution of a permanganate. By including such an inorganic filler or polymer, these form fine island-in-sea structures or disperse, so when using the curable resin composition of the present invention to obtain the later explained electrical insulating layer and treat it by an aqueous solution of a permanganate, the advantage is obtained of these selectively dissolving or detaching and thereby enabling control of the surface roughness of the electrical insulating layer.

As an example of a polymer which can dissolve in an aqueous solution of a permanganate, a liquid epoxy resin, polyester resin, bismaleimide-triazine resin, silicone resin, polymethyl methacrylic resin, natural rubber, styrene-based rubber, isoprene-based rubber, butadiene-based rubber, nitrile-based rubber, ethylene-based rubber, propylene-based rubber, urethane rubber, butyl rubber, silicone rubber, fluororubber, norbornene rubber, ether-based rubber, etc. may be mentioned.

There is no special limitation on the ratio of the polymer which can dissolve in an aqueous solution of a permanganate. It is usually 1 to 60 parts by weight with respect to 100 parts by weight of the alicyclic olefin polymer (A), preferably 3 to 25 parts by weight, more preferably 4 to 40 parts by weight.

As examples of the inorganic filler, calcium carbonate, magnesium carbonate, barium carbonate, zinc oxide, titanium oxide, magnesium oxide, magnesium silicate, calcium silicate, zirconium silicate, hydrated alumina, magnesium hydroxide, aluminum hydroxide, barium sulfate, silica, talc, clay, etc. may be mentioned. Among these as well, calcium carbonate and silica are preferable since fine grains are easily obtained and detachment in an aqueous solution of a permanganate can be easily controlled. These inorganic fillers may be treated on their surfaces by a silane coupling agent or stearic acid or other organic acid.

The inorganic filler is preferably a nonconductive one which does not lower the dielectric characteristics of the obtained electrical insulating layer. Further, the inorganic filler is not particularly limited in shape. Spheres, fibers, plates, etc. are possible, but to obtain a fine rough surface shape, fine spheres are preferable.

The inorganic filler has an average particle size of usually 0.008 μm or more and less than 2 μm, preferably 0.01 μm or more and less than 1.5 μm, particularly preferably 0.02 μm or more and less than 1 μm. Note that, the average particle size can be measured by a particle size distribution measuring device.

The amount of the inorganic filler which is blended in is, for example, sutably selected in accordance with the extent of adhesion to the conductor layer which is required in the cured product of the curable resin composition of the present invention, but is usually 1 to 80 wt %, preferably 2 to 70 wt %, more preferably 5 to 50 wt % in the curable resin composition of the present invention.

Further, the curable resin composition of the present invention may further contain, in accordance with need, a flame retardance aid, heat resistance stabilizer, weather resistance stabilizer, anti-aging agent, ultraviolet absorbent (laser workability improver), leveling agent, antistatic agent, slip agent, antiblocking agent, antifogging agent, lubricant, dye, natural oil, synthetic oil, wax, emulsion, magnetic material, dielectric characteristic adjusting agent, toughness agent, or any other ingredient. The ratio of these optional ingredients added may be suitably selected in a range not detracting from the object of the present invention.

The method of production of the curable resin composition of the present invention is not particularly limited. The above ingredients may be mixed as they are or may be mixed in a state dissolved or dispersed in an organic solvent. It is also possible to prepare a composition in the state with part of the above ingredients dissolved or dispersed in an organic solvent and mix the remaining ingredients in the composition.

(Sheet-Shaped or Film-Shaped Article)

The sheet-shaped or film-shaped article of the present invention is comprised of the above-mentioned curable resin composition formed into a sheet shape or film shape. The shaped article includes the curable resin composition of the present invention impregnated in a fiber base material which is made into a sheet-shaped or film-shaped composite shaped article.

The sheet-shaped or film-shaped article of the present invention can, for example, be obtained by adding an organic solvent to the curable resin composition of the present invention in accordance with need and coating, spraying, or casting the composition on a support member, then drying it.

As the support member which is used at this time, a resin film or metal foil etc. may be mentioned. As a resin film, a polyethylene terephthalate film, polypropylene film, polyethylene film, polycarbonate film, polyethylene naphthalate film, polyarylate film, nylon film, etc. may be mentioned. Among these films, from the viewpoint of the heat resistance, chemical resistance, peelability, etc., a polyethylene terephthalate film or polyethylene naphthalate film is preferable. As the metal foil, copper foil, aluminum foil, nickel foil, chrome foil, gold foil, silver foil, etc. may be mentioned.

The thickness of the sheet-shaped or film-shaped article is not particularly limited, but from the viewpoint of the workability etc., it is usually 1 to 150 μm, preferably 2 to 100 μm, more preferably 5 to 80 μm. Further, the surface average roughness Ra of the support member is usually 300 nm or less, preferably 150 nm or less, more preferably 100 nm or less.

As the method of coating the curable resin composition of the present invention, dip coating, roll coating, curtain coating, die coating, slit coating, gravure coating, etc. may be mentioned.

Note that, in the shaped article which is used in the present invention, the curable resin composition of the present invention is preferably uncured or semicured in state. Here, the “uncured” means the state where substantially all of the alicyclic olefin polymer (A) dissolves when dipping the shaped article in a solvent which can dissolve the alicyclic olefin polymer (A). Further, the “semicured” means the state where of being cured to an intermediate point to an extent where further curing is possible if heated, preferably a state where part of the alicyclic olefin polymer (A) (specifically 7 wt % or more) is dissolved in a solvent which can dissolve the alicyclic olefin polymer (A) or a state where the volume after dipping the shaped article in a solvent for 24 hours is 200% or more of the volume before dipping (swelling rate).

The drying temperature when coating the curable resin composition of the present invention on a support member, then drying it is preferably made a temperature of an extent whereby the curable resin composition of the present invention does not cure. It is usually 20 to 300° C., preferably 30 to 200° C. If the drying temperature is too high, the curing reaction is liable to proceed too much and the obtained shaped article no longer remains in the uncured or semicured state. Further, the drying time is usually 30 seconds to 1 hour, preferably 1 minute to 30 minutes.

Further, when making the sheet-shaped or film-shaped article of the present invention a sheet-shaped or film-shaped composite shaped article, for example, it is possible to obtain by adding an organic solvent to the curable resin composition of the present invention in accordance with need, then impregnating it in a fiber base material, then drying it. In this composite shaped article as well, the curable resin composition of the present invention is preferably contained in an uncured or a semicured state.

As the fiber base material which is used in this case, for example, a roving cloth, chopped mat, surfacing mat, or other woven fabric or unwoven fabric; fiber bundles or masses etc. may be mentioned. Among these fiber base materials, from the viewpoint of dimensional stability, a woven fabric is preferable, while from the viewpoint of the workability, a nonwoven fabric is preferable.

The thickness of the sheet-shaped or film-shaped composite shaped article is not particularly limited, but from the viewpoint of the workability etc., it is usually 1 to 150 μm, preferably 2 to 100 μm, more preferably 5 to 80 μm. Further, the amount of the fiber base material in the composite shaped article is usually 20 to 90 wt %, preferably 30 to 85 wt %.

The method of impregnating the curable resin composition of the present invention in the fiber base material is not particularly limited, but the method of adjusting the viscosity etc. by adding an organic solvent to the curable resin composition of the present invention and dipping the fiber base material in the curable resin composition to which the organic solvent is added, the method of coating or spraying the curable resin composition to which the organic solvent is added on the fiber base material, etc. may be mentioned. In the method of coating or spraying, it is possible to place the fiber base material on a support member and coat or spray the curable resin composition to which the organic solvent is added on this. Furthermore, it is also possible to lay a protective film on this and press it from above by a roller etc. (iron it) so as to promote the impregnation of the curable resin composition in the fiber base material.

Further, as the drying temperature when impregnating the curable resin composition of the present invention in a fiber base material, then drying it, a temperature of an extent where the curable resin composition of the present invention does not cure is preferable. It is usually 20 to 300° C., preferably 30 to 200° C. If the drying temperature is too high, the curing reaction is liable to proceed too much and the obtained composite shaped article no longer remains in the uncured or semicured state. Further, the drying time is usually 30 seconds to 1 hour, preferably 1 minute to 30 minutes.

Furthermore, the sheet-shaped or film-shaped article of the present invention may be a laminated shaped article comprised of at least one layer made of the curable resin composition of the present invention (including arbitrary fiber base material as well). The layers which form the laminated shaped article may partially include layers comprised of a known curable resin composition which has a composition different from the curable resin composition of the present invention. By combining and laminating a plurality of layers comprised of resin compositions which have different compositions, it is possible to obtain a shaped article with a good balance having various characteristics in addition to those of the shaped article of the present invention. Such a laminated shaped article can be produced by, for example, the method of coating, spraying, or casting the curable resin composition of the present invention on a support member and drying the same so as to form a first resin layer, next laying a fiber base material on the first resin layer and coating or casting the curable resin composition of the present invention, but a curable resin composition which has a composition different from the one used for the first resin layer, or arbitrary curable resin composition which has a composition which is different from the curable resin composition of the present invention, on the fiber base material while impregnating the fiber base material and drying the same so as to form a second resin layer which contains a fiber base material on the first resin layer.

The shaped article which is obtained in the above way is used in a state attached to the support member or peeled off from the support member.

(Cured Product and Surface Treated Cured Product)

The cured product of the present invention is obtained by curing the above-mentioned curable resin composition of the present invention or the sheet-shaped or film-shaped article of the present invention.

The curing conditions are suitably selected in accordance with the type of the curing agent (B). The curing temperature is usually 30 to 400° C., preferably 70 to 300° C., more preferably 100 to 200° C. Further, the curing time is 0.1 to 5 hours, preferably 0.5 to 3 hours. The method of heating is not particularly limited, but for example an electric oven can be used for it.

The surface treated cured product of the present invention is obtained by treating the surface of the cured product for surface roughening by an aqueous solution of a permanganate and plating it by nonelectrolytic plating after surface roughening. Note that, the surface roughening conditions and nonelectrolytic platng conditions in this case may be made ones similar to those described in the explanation of the multilayer circuit board explained later.

(Laminate)

The laminate of the present invention is comprised of a board which has a conductor layer on its surface and a layer comprised of the cured product or surface treated cured product of the above-mentioned present invention. The layer comprised of the cured product or the surface treated cured product of the present invention functions as an electrical insulating layer in the laminate of the present invention.

The board which has the conductor layer at its surface is comprised of an electrical insulating board which has a conductor layer on its surface. The electrical insulating board is formed by curing a curable resin composition which contains a known electrical insulating material (for example, alicyclic olefin polymer, epoxy resin, maleimide resin, (meth)acrylic resin, diallyl phthalate resin, triazine resin, polyphenylether resin, fully aromatic polyester resin, polyimide resin, glass, etc.). The conductor layer is not particularly limited, but usually is a layer which contains interconnects which are formed from a conductive metal or other conductor and may further include various circuits. The configuration, thickness, etc. of the interconnects or circuits are not particularly limited. As specific examples of the board which has the conductor layer on its surface, a printed circuit board, silicon wafer board, etc. may be mentioned. The thickness of the board which has the conductor layer on its surface is usually 10 μm to 10 mm, preferably 20 μm to 5 mm, more preferably 30 μm to 2 mm.

The board which has the conductor layer on its surface which is used in the present invention preferably is pretreated on the surface of the conductor layer so as to improve the adhesion with the electrical insulating layer. For the method of pretreatment, known art can be used without particular limitation. For example, if the conductor layer is one comprised of copper, the oxidation method of bringing a strong alkali oxidizing solution into contact with the surface of the conductor layer to form a layer of copper oxide on the conductor surface for roughening it, the method of oxidizing the surface of the conductor layer by the above method, then reducing it by hydrogenated boron sodium, formalin, etc., the method of depositing plating on the conductor layer for roughening, the method of bringing an organic acid into contact with the conductor layer to dissolve out the grain boundaries of the copper for roughening, the method of forming a primer layer on the conductor layer by a thiol compound or silane compound etc., etc. may be mentioned. Among these, from the viewpoint of the ease of maintaining the shapes of fine interconnect patterns, the method of bringing an organic acid into contact with the conductor layer to dissolve out the grain boundaries of the copper for roughening and the method of forming a primer layer by a thiol compound or silane compound etc. are preferable.

The laminate of the present invention usually can be produced by hot press bonding the above-mentioned sheet-shaped or film-shaped article of the present invention on a board which has a conductor layer on its surface, curing that shaped article, and thereby forming an electrical insulating layer comprised of a cured product of the present invention.

As the method of hot bonding, the method of laying a shaped article equipped with a support member so as to contact the conductor layer of the above-mentioned board and hot press bonding (laminating) this using a press laminator, press, vacuum laminator, vacuum press, roll laminator, or other pressing machine may be mentioned. By hot pressing, it is possible to make the conductor layer of the surface of the board and the shaped article bond without substantial presence of spaces at their interface.

The temperature of the hot bonding operation is usually 30 to 250° C., preferably 70 to 200° C., the pressure which is applied is usually 10 kPa to 20 MPa, preferably 100 kPa to 10 MPa, and the time is usually 30 seconds to 5 hours, preferably 1 minute to 3 hours. Further, the hot bonding is preferably performed under reduced pressure so as to improve the ability to bury interconnect patterns and suppress the formation of gas bubbles. The pressure of the atmosphere for performing the hot bonding is usually 100 kPa to 1 Pa, preferably 40 kPa to 10 Pa.

Further, the hot press bonded shaped article is cured and an electrical insulating layer is formed so as to produce the laminate of the present invention. The curing is usually performed by heating the board as a whole on the conductor layer of which a shaped article is laminated. The curing may be performed simultaneously with the above-mentioned hot press bonding operation. Further, first, the hot press bonding operation may be performed under conditions not causing curing, that is, a relative low temperature and short time, and then the curing performed.

Further, for the purpose of improving the flatness of the electrical insulating layer or for the purpose of increasing the thickness of the electrical insulating layer, it is also possible to bond together and laminate at least two shaped articles on the conductor layer of the board.

In the present invention, the surface of the electrical insulating layer which forms the thus obtained laminate may be treated for surface roughening by an aqueous solution of a permanganate and the surface roughened electrical insulating layer may be nonelectrolytic plated. In this case, a laminate which is comprised of a board having a conductor layer on its surface and a layer comprised of the surface treated cured product of the present invention laminated together is obtained. Note that, in this case, the surface roughening conditions and nonelectrolytic plating conditions should be made the same as those described in the explanation of the multilayer circuit board explained later.

(Multilayer Circuit Board)

In the present invention, it is possible to form a further other conductor layer on the electrical insulating layer of a laminate of the present invention mentioned above so as to obtain a multilayer circuit board. Below, the method of production of a multilayer circuit board will be explained.

First, the laminate is formed with via holes or through holes which pass through the electrical insulating layers. The via holes or through holes, in the case of making a multilayer circuit board, are formed for connecting the conductor layers which form the multilayer circuit board. The via holes or through holes can be formed by chemical treatment such as photolithography or drilling, lasering, plasma etching, or other physical treatment etc. Among these methods as well, the method of using a laser (CO₂ gas laser, excimer laser, UV-YAG laser, etc.) is preferable since it enables the formation of finer via holes without causing a drop in the characteristics of the electrical insulating layer.

Next, the surface of the electrical insulating layer (that is, the cured product of the present invention) of the laminate is treated for surface roughening by an aqueous solution of a permanganate. The surface roughening treatment is performed for improving the adhesion with the conductor layer which is formed on the electrical insulating layer.

The surface roughening method is not particularly limited, but, for example, the method of bringing an aqueous solution of a permanganate into contact with an electrical insulating layer etc. may be mentioned. The method of bringing an aqueous solution of a permanganate into contact with the surface of the electrical insulating layer is not particularly limited, but, for example, the dipping method of dipping the electrical insulating layer in an aqueous solution of a permanganate, the liquid buildup method of utilizing the surface tension of an aqueous solution of a permanganate to place an aqueous solution of a permanganate on the electrical insulating layer, the spray method of spraying an aqueous solution of a permanganate on an electrical insulating layer, etc. may be used. By performing treatment for surface roughening, the adhesion of the electrical insulating layer with the conductor layer or other layer can be improved. Note that, as the permanganate, potassium permanganate or sodium permanganate etc. may be mentioned.

The temperature or time when bringing an aqueous solution of a permanganate into contact with the surface of an electrical insulating layer to perform surface roughening treatment is not particularly limited, but the temperature is usually 30 to 95° C., preferably 50 to 90° C., and the time is usually 1 to 90 minutes, preferably 3 to 60 minutes. The cured product of the present invention which forms the electrical insulating layer is comprised of the above-mentioned curable resin composition of the present invention which is cured, so even when changing the conditions at the time of surface roughening treatment (for example, when lengthening the treatment time), the surface roughness can be held low. For this reason, according to the present invention, it is possible, without controlling the surface roughening conditions with a high precision, to make the surface roughened electrical insulating layer (the cured product of the present invention) one with a surface average roughness Ra of preferably 1 to 300 nm, more preferably 5 to 200 nm in range. Note that, in this Description, the “Ra value” is one type of numerical value which shows the surface roughness and is called the “arithmetic average roughness”. Specifically, it is the value obtained by measuring the absolute values of heights which change in a measurement region from the average line, that is, the surface, and obtaining the arithmetic average. For example, it is possible to use a WYKO NT1100 made by Veeco Instruments and find it from the numerical values which are obtained in the VSI contact mode by a fiftyfold lens in a measurement range of 120 μm×91 μm.

Further, to remove the aqueous solution of a permanganate after the surface roughening, the surface roughened electrical insulating layer is washed with water, next, for the purpose of removing the coating film of the manganese dioxide which is formed by the surface roughening treatment, performing neutralization and reduction by a mixed solution of hydroxyamine sulfate and sulfuric acid or other acidic aqueous solution are preferable.

Next, after the electrical insulating layer of the laminate is treated to roughen its surface, then a conductor layer is formed on the surface of the electrical insulating layer and the inside wall surfaces of the via holes.

The method of formation of the conductor layer is not particularly limited, but from the viewpoint of formation of a conductor layer which is excellent in adhesion, a plating method is preferable.

The method of forming a conductor layer by the plating method is not particularly limited. For example, it is possible to employ the method of forming a metal thin film on the electrical insulating layer by plating etc., then grow a metal layer by plating up.

For example, when forming a metal thin film by nonelectrolytic plating, before forming the metal thin film on the surface of the electrical insulating layer, the general practice is to deposit silver, palladium, zinc, cobalt, or other catalytic nuclei on the electrical insulating layer. The method of depositing the catalytic nuclei on the electrical insulating layer is not particularly limited. For example, the method of dipping in a solution of a silver, palladium, zinc, cobalt, or other metal compound or their salts or complexes in water or alcohol or chloroform or other organic solvent in 0.001 to 10 wt % in concentration (including, in accordance with need, an acid, alkali, complexing agent, reducing agent, etc.), then reducing the metal etc. may be mentioned.

As the nonelectrolytic plating solution which is used in the nonelectrolytic plating method, a known self catalyst type nonelectrolytic plating solution may be used. The type of metal, the type of reducing agent, the type of complex agent, the concentration of hydrogen atoms, the concentration of dissolved oxygen, etc. which are contained in the plating solution are not particularly limited. For example, a nonelectrolytic copper plating solution which uses ammonium hypophosphite, hypophosphorus acid, hydrogenated boron-ammonium, hydrazine, formalin, etc. as a reducing agent; a nonelectrolytic nickel-phosphorus plating solution which uses sodium hypophosphite as a reducing agent; a nonelectrolytic nickel-boron plating solution which uses dimethylamine borane as a reducing agent; a nonelectrolytic palladium plating solution; a nonelectrolytic palladium-phosphorus plating solution which uses sodium hypophosphite as a reducing agent; a nonelectrolytic gold plating solution; a nonelectrolytic silver plating solution; a nonelectrolytic nickel-cobalt-phosphorus plating solution which uses sodium hypophosphite as a reducing agent, and other nonelectrolytic plating solutions may be used.

After forming the metal thin film, it is possible to bring the surface of the board into contact with a rustproofing agent for rustproofing. Further, after forming the metal thin film, it is possible to heat the metal thin film for improvement of the adhesion etc. The heating temperature is usually 50 to 350° C., preferably 80 to 250° C. Note that, at this time, the heating may be performed under a pressurized condition. As the pressurizing method at this time, for example, the method of using a hot press, pressurized heating roll machine, or other physical pressurizing means may be mentioned. The added pressure is usually 0.1 to 20 MPa, preferably 0.5 to 10 MPa. If in this range, a high adhesion is secured between the metal thin film and electrical insulating layer.

Resist patterns for plating are formed on the metal thin film which is formed in this way, the plating is made to grow on it by electroplating or other wet plating (plating up), next, the resist is removed and further etching is used to etch the metal thin film to pattern shapes to form a conductor layer. Therefore, the conductor layer which is formed by this method is usually comprised of pattern shapes of metal thin film and a plating which is grown on them.

The multilayer circuit board which was obtained in the above way was made a board for producing the above-mentioned laminate, and this was hot press bonded with the above-mentioned shaped article of the present invention and cured to form an electrical insulating layer, a conductor layer was formed on this in accordance with the above-mentioned method, and these steps were repeated to form further layers. Due to this, it is possible to obtain a desired multilayer circuit board.

The above-mentioned multilayer circuit board has a cured product obtained by curing the curable resin composition of the present invention as an electrical insulating layer. This electrical insulating layer has a small surface roughness when treating the surface by an aqueous solution of a permanganate, is excellent in adhesion with the conductor layer, is high in peel strength, and is excellent in electrical characteristics as well. For this reason, such a multilayer circuit board can be suitably used as a board in a computer or mobile phone or other electronic device for mounting a CPU or memory or other semiconductor device or other component.

### EXAMPLES

Below, examples and comparative examples will be given to explain the present invention more specifically. Note that, the parts and % in the examples are based on weight unless particularly indicated otherwise. The various physical properties were evaluated by the following methods.

(1) Amount of monomer in polymerization solution: The polymerization solution was diluted by tetrahydrofuran and was measured by gas chromatography (GC) to find the amount of the monomer in the polymerization solution.

(2) Number average molecular weight (Mn) and weight average molecular weight (Mw) of polymer: Using tetrahydrofuran as a development solvent, this was measured by gel permeation chromatography (GPC) and found as a value converted to polystyrene.

(3) Hydrogenation rate of polymer: The hydrogenation rate means the ratio of the number of moles of unsaturated bonds which are hydrogenated with respect to the number of unsaturated bonds in the polymer before hydrogenation and was found by ¹H-NMR spectral measurement at 400 MHz.

(4) Content of repeating units having carboxylic anhydride groups of polymer: This means the ratio of the number of moles of repeating units having carboxylic anhydride groups with respect to the number of moles of the total monomer units in the polymer and was found by ¹H-NMR spectral measurement at 400 MHz.

(5) Viscosity of varnish: An E type viscosity meter was used to measure the dynamic viscosity at 25° C.

(6) Adhesion (peel strength) of insulating film and metal layer: The peel strength of the insulating film and copper plating layer at the sample (multilayer printed circuit board) was measured based on JIS C6481-1996. The results were used as the basis for judgment by the following criteria.

Excellent: Minimum value of peel strength 6N/cm or more

Good: Minimum value of peel strength 4N/cm or more and less than 6N/cm

Unacceptable: Minimum value of peel strength less than 4N/cm

(7) Surface roughness of insulating film (arithmetic average roughness Ra): The surface of a sample (multilayer printed circuit board) was measured for surface roughness (arithmetic average roughness Ra) using a surface shape measuring device (WYKO NT1100 made by Veeco Instruments) in a measurement range of 91 μm×120 μm.

(8) Evaluation of patterning ability: 100 interconnect patterns of interconnect widths of 20 μm, interconnect pitches of 20 μm, and interconnect lengths of 1 cm were formed. Samples with no disturbances in any of the 100 were evaluated as “excellent”, those with slight disturbances in shape such as rising, but with no damage such as peeling were evaluated as “good”, and those with damage were evaluated as “unacceptable”.

### Synthesis Example 1 of Alicyclic Olefin Polymer (A)

As a first stage of polymerization, 5-ethylidene-bicyclo[2.2.1]hept-2-ene (below abbreviated as “EdNB”) 35 mol parts, 1-hexene 0.9 mol part, anisole 340 mol parts, and a ruthenium-based polymerization catalyst comprised of 4-acetoxybenzylidene(dichloro)(4,5-dibromo-1,3-dimesityl-4-imidazolin-2-ylidene)(tricyclohexyl-phosphine)ruthenium (C1063, made by Wako Pure Chemicals) 0.005 mol part were charged into a nitrogen-substituted pressure resistant glass reactor and subjected to a polymerization reaction under stirring at 80° C. for 30 minutes to obtain a solution of a norbornene-based ring-opening polymer.

Next, as a second stage of polymerization, to the solution obtained in the first stage of polymerization, tetracyclo[9.2.1.0^{2,10}0.^{3,8}]tetradeca-3,5,7,12-tetraene(methanotetrahydrofluorene, below abbreviated as “MTF”) 35 mol parts, bicyclo[2.2.1]hept-2-ene-5,6-dicarboxylic anhydride (below abbreviated as “NDCA”) 30 mol parts, anisole 250 mol parts, and C1063 0.01 mol part were added and the mixture subjected to a polymerization reaction under stirring at 80° C. for 1.5 hours to obtain a solution of a norbornene-based ring-opening polymer. This solution was measured by gas chromatography, whereupon it was confirmed that substantially no monomer remained. The polymerization conversion rate was 99% or more.

Next, to a nitrogen-substituted autoclave equipped with agitator, the obtained solution of the ring-opening polymer was charged, C1063 0.03 mol part was added, and the mixture was agitated at 150° C. at a hydrogen pressure of 7 MPa for 5 hours to cause a hydrogenation reaction and obtain a solution of a hydrogenated product of a norbornene-based ring-opening polymer comprised of the alicyclic olefin polymer (A-1). The obtained polymer (A-1) had a weight average molecular weight of 60,000, a number average molecular weight of 30,000, and a molecular weight distribution of 2. Further, the hydrogenation rate was 95%, while the content of the repeating units having the carboxylic anhydride groups was 30 mol %. The solids concentration of the solution of the polymer (A-1) was 22%.

### Synthesis Example 2 of Alicyclic Olefin Polymer (A)

MTF 70 mol parts, NDCA 30 mol parts, 1-hexene 0.9 mol part, anisole 590 mol parts, and C1063 0.015 mol part were charged into a nitrogen-substituted pressure resistant glass reactor and subjected to a polymerization reaction while stirring at 80° C. for 1 hour to obtain a solution of a norbornene-based ring-opening polymer. This solution was measured by gas chromatography, whereupon it was confirmed that substantially no monomer remained. The polymer conversion rate was 99% or more.

Next, to a nitrogen-substituted autoclave with an agitator attached, a solution of the obtained ring-opening polymer was charged. This was agitated at 150° C. and a hydrogen pressure of 7 MPa for 5 hours to cause a hydrogenation reaction and obtain a solution of a hydrogenated product of a norbornene-based ring-opening polymer comprised of the alicyclic olefin polymer (A-2). The obtained polymer (A-2) had a weight average molecular weight of 50,000, a number average molecular weight of 26,000, and a molecular weight distribution of 1.9. Further, the hydrogenation rate was 97%, and the content of the repeating units having carboxylic anhydride groups was 30 mol %. The solid content concentration of the solution of the polymer (A-2) was 22%.

### Synthesis Example 3 of Alicyclic Olefin Polymer (A)

MTF 70 mol parts, NDCA 30 mol parts, 1-hexene 6 mol parts, anisole 590 mol parts, and C1063 0.015 mol part were charged in a nitrogen-substituted pressure resistant glass reactor and subjected to a polymerization reaction while being agitated at 80° C. for 1 hour to obtain a solution of a ring-opening polymer. This solution was measured by gas chromatography, whereupon it was confirmed that substantially no monomer remained. The polymer conversion rate was 99% or more.

Next, to a nitrogen-substituted autoclave with an agitator attached, a solution of the obtained ring-opening polymer was charged. This was agitated at 150° C. and a hydrogen pressure of 7 MPa for 5 hours to cause a hydrogenation reaction. Next, the obtained hydrogenated reaction solution was concentrated to obtain an alicyclic olefin polymer (A-3). The obtained polymer (A-3) had a weight average molecular weight of 10,000, a number average molecular weight of 5,000, and a molecular weight distribution of 2. Further, the hydrogenation rate was 97%, and the content of the repeating units having carboxylic anhydride groups was 30 mol %. The solid content concentration of the solution of the polymer (A-3) was 55%.

### Example 1

### Curable Resin Composition (B-1)

A solution of the polymer (A-1) 450 parts and a silica slurry 113 parts which was obtained by dispersing spherical silica (Admafine (registered trademark) SO-C1, made by Admatechs, volume average particle size 0.25 μm) 40% and the polymer (A-2) 2% in anisole were mixed and agitated by a planetary type agitator for 3 minutes.

To this, a curing agent (B) comprised of a solution of a polyfunctional epoxy resin (1032H60, made by Mitsubishi Chemical, epoxy equivalent 163 to 175) dissolved in anisole in 70%:35.8 parts, a laser workability improver comprised of 2-[2-hydroxy-3,5-bis(α,α-dimethylbenzyl)phenyl]-2H-benzotriazole 1 part, a hindered phenol compound (C) comprised of tris(3,5-di-t-butyl-4-hydroxybenzyl)-isocyanulate (IRGANOX (registered trademark) 3114, made by Ciba Speciality Chemicals) 1 part, a hindered amine compound (D-1) comprised of tetrakis(1,2,2,6,6-pentamethyl-4-piperidyl) 1,2,3,4-butanetetracarboxylate (ADK STAB (registered trademark) LA52, made by ADEKA) 1 part, an elastomer comprised of a solution of liquid epoxylated polybutadiene (Ricon (registered trademark) 657, made by Sartomer Japan) dissolved in anisole in 80%:3 parts, and anisole 553 parts were mixed and agitated by a planetary type agitator for 3 minutes.

Furthermore, to this, a curing accelerator comprised of a solution dissolved in 1-benzyl-2-phenylimidazole dissolved in anisole in 5%:10 parts and agitated by a planetary type agitator for 5 minutes to obtain a varnish of the curable resin composition (B-1). The varnish had a viscosity of 70 mPa·sec.

### Production Example 2

### Curable Resin Composition (B-2)

A solution of the polymer (A-2) 44 parts, a solution of the polymer (A-3) 32 parts, and a silica slurry 863 parts which was obtained by mixing surface treated spherical silica (Admafine SC-2500-SXJ, made by Admatechs, treated by aminosilane type silane coupling agent) 78% and the polymer (A-3) 2% with anisole, treatihng it by a high pressure homogenizer for 15 minutes to disperse it and stirring the mixture by a planetary type agitator for 3 minutes.

To this, a curing agent (B) comprised of a fluorene-based epoxy resin (OGSOL PG-100 (registered trademark), made by Osaka Gas Chemical, epoxy equivalent 163 to 175) 123 parts, bisphenol A type epoxy resin [Epicoat (registered trademark) 828EL, made by Mitsubishi Chemical, epoxy equivalent 184 to 194] 28 parts, polyfunctional epoxy resin 1032H60 23 parts, an anti-aging agent comprised of tris(3,5-di-t-butyl-4-hydroxybenzyl)-isocyanulate 1 part, dicyclopentadiene-type novolac resin (GDP-6095LR, made by GUN EI Chemical Industry) 81 parts, and a solution of CP-002 (mixture of fluorine-based phenol monomer and bisphenol A, made by Osaka Gas Chemical) dissolved in anisole to 50%:60 parts were mixed and agitated by a planetary type agitator for 3 minutes. Furthermore, to this, a curing accelerator comprised of a solution of 1-benzyl-2-phenylimidazole dissolved in anisole to 5%:25 parts was mixed. The mixture was agitated by a planetary type agitator for 5 minutes to obtain a varnish of the curable resin composition (B-2). The viscosity of the varnish was 2300 mPa·sec.

### Example 2

A varnish of the curable resin composition (B-1) was coated on a thickness 100 μm polyethylene terephthalate film (support member) by a wire bar, then was dried in a nitrogen atmosphere at 130° C. for 10 minutes to obtain a film equipped with the support member (C-1) on which a thickness 3 μm resin layer of the uncured curable resin composition (B-1) is formed.

Next, on the surface of the curable resin composition (B-1) of the film equipped with the support member (C-1), a varnish of the curable resin composition (B-2) was coated using a doctor blade (made by Tester Sangyo Co., Ltd.) and an autofilm applicator (made by Tester Sangyo Co., Ltd.) Next, this was dried in a nitrogen atmosphere at 80° C. for 10 minutes to obtain a film equipped with the support member (C-2) on which a total thickness 40 μm resin layer of the curable resin composition is formed. The film equipped with the support member (C-2) was formed with the support member, resin layer of the curable resin composition (B-1), and resin layer of the curable resin composition (B-2) in that order.

A varnish which contains a glass filler and halogen-free epoxy resin was impregnated in glass fiber to obtain a core material. On the two surfaces, thickness 18 μm copper films were bonded to obtain a thickness 0.8 mm, 150 mm square (vertical 150 mm, horizontal 150 mm) two-sided copper-clad board. On the surface, a conductor layer is formed with an interconnect width and interconnect pitch of 50 μm, thickness of 18 μm, and surface microetched by contact with an organic solvent to obtain an inside layer board.

At the two surfaces of this inside layer board, sheets of the above-mentioned film equipped with the support member (C-2) which were cut into 150 mm squares were bonded so that the resin shaped article film sides were at the insides, then the assembly was pressed by primary pressing. The primary pressing was hot press bonded by a vacuum laminator provided with heat resistant rubber press plates at the top and bottom under a reduced pressure of 200 Pa at a temperature of 110° C., and a pressure of 0.1 MPa for 90 seconds. Furthermore, a hydraulic press apparatus provided with metal press plates at the top and bottom was used for hot press bonding by a press bonding temperature of 110° C. at 1 MPa for 90 seconds. Next, the support member was peeled off to thereby obtain a laminate of a resin layer of a curable resin composition and an inside layer board. Furthermore, the laminate was allowed to stand in an air atmosphere at 180° C. for 60 minutes and the resin layer was made to cure so as to form an electrical insulating layer on the inside layer board.

(Swelling Step)

The obtained laminate was dipped for 15 minutes in a swelling solution comprised of a 60° C. aqueous solution which was prepared to give Swelling Dip Securigant P (registered trademark) (made by Atotech) 500 ml/liter and sodium hydroxide 3 g/liter while shaking, then was rinsed with water.

(Oxidation Step)

Next, the swelled laminate was dipped in a 80° C. aqueous solution which was prepared to give a concentration of an aqueous solution of a permanganate comprised of Concentrate Compact CP (made by Atotech) of 500 ml/liter and a concentration of sodium hydroxide of 40 g/liter for 30 minutes with shaking, then was rinsed with water.

(Neutralizing and Reduction Step)

Next, the oxidized laminate was dipped in a 40° C. aqueous solution which was prepared to give a concentration of a hydroxylamine sulfate aqueous solution comprised of Reduction Securiganth P 500 (registered trademark) (made by Atotech) of 100 ml/liter and sulfuric acid of 35 ml/liter for 5 minutes for neutralization and reduction, then was rinsed with water.

(Cleaner/Conditioner Step)

Next, the laminate was dipped in a 50° C. aqueous solution which was prepared to give a concentration of a cleaner/conditioner aqueous solution comprised of ALCUP MCC-6-A (made by Uyemura) of 50 ml/liter for 5 minutes for cleaner/conditioner treatment. Next, the neutralized and reduced laminate was dipped in a 40° C. aqueous washing water for 1 minute, then was rinsed with water.

(Soft Etching Step)

Next, the cleaner/conditioner treated laminate was dipped in an aqueous solution which was prepared to give a sulfuric acid concentration of 100 g/liter and sodium persulfate of 100 g/liter for 2 minutes for soft etching, then was rinsed with water.

(Pickling Step)

Next, the soft etched laminate was dipped in an aqueous solution which was prepared to given a sulfuric acid concentration of 100 g/liter for 1 minute for pickling, then was rinsed with water.

(Catalyst Imparting Step)

Next, the pickled laminate was dipped in a 60° C. Pd salt-containing plating catalyst aqueous solution which was prepared to give ALCUP Activator MAT-1-A (made by Uyemura) of 200 ml/liter, ALCUP Activator MAT-1-B (made by Uyemura) of 30 ml/liter, and sodium hydroxide of 0.35 g/liter for 5 minutes, then was rinsed with water.

(Activation Step)

Next, the catalyst treated laminate was dipped in an aqueous solution which was prepared to give ALCUP Reducer MAB-4-A (made by Uyemura) of 20 ml/liter and ALCUP Reducer MAB-4-B (made by Uyemura) of 200 ml/liter at 35° C. for 3 minutes to reduce the plating catalyst, then was rinsed with water.

(Accelerator Treatment Step)

Next, the laminate after finishing the activation step was dipped in an aqueous solution which was prepared to give ALCUP Accelerator MEL-3-A (made by Uyemura) of 50 ml/liter at 25° C. for 1 minute.

(Nonelectrolytic Plating Step)

The thus obtained laminate was dipped in a nonelectrolytic copper plating solution which was prepared to give THRU-CUP PEA-6-A (made by Uyemura) of 100 ml/liter, THRU-CUP PEA-6-B-2X (made by Uyemura) of 50 ml/liter, THRU-CUP PEA-6-C (made by Uyemura) of 14 ml/liter, THRU-CUP PEA-6-D (made by Uyemura) of 15 ml/liter, THRU-CUP PEA-6-E (made by Uyemura) of 50 ml/liter, and 37% formalin aqueous solution of 5 ml/liter, while blowing in air, at a temperature of 36° C. for 20 minutes for nonelectrolytic copper plating so as to form a thin film layer of metal on the laminate surface. Next, it was dipped in a rustproofing solution which was prepared to give AT-21 (made by Uyemura) of 10 ml/liter at room temperature for 1 minute, then was rinsed with water. Furthermore, this was dried to prepare a rustproofed laminate. This rustproofed laminate was annealed in an air atmosphere at 150° C. for 30 minutes.

The annealed laminate was electroplated with copper to form a thickness 18 μm electroplated copper film. Next, the laminate was heat treated at 180° C. for 60 minutes to thereby obtain a multilayer printed circuit board

A which is comprised of a laminate on which conductor layers comprised of the metal thin film layers and electroplated copper films are formed thereby giving two layers on the two surfaces. This multilayer printed circuit board was measured for peel strength.

Further, the annealed laminate had a commercially available dry film of a photosensitive resist atached to it by hot bonding. Next, this dry film was covered with a mask of evaluation-use patterns and exposed, then developed to obtain resist patterns. Next, the laminate was dipped in an aqueous solution of sulfuric acid 50 ml/liter at 25° C. for 1 minute to remove the rustproofing agent and was electroplated with copper at the parts where the resist was not formed so as to form a thickness 18 μm electrolytic copper plating film. After that, the resist patterns on the laminate were removed using a stripping solution and surface was etched by a mixed solution of cupric chloride and hydrochloric acid. Next, the laminate was heat treated at 180° C. for 60 minutes to thereby obtain a multilayer printed circuit board B with interconnect patterns comprised of a laminate on which circuits are formed by the metal thin film layers and electroplated copper films thereby giving two layers on the two surfaces. The electrical insulating layer at the parts of the multilayer printed circuit board B with no conductor circuits was measured for surface average roughness Ra and was evaluated for patterning ability. The results of evaluation are shown in Table 1.

### Example 3

Except for making the tetrakis(1,2,2,6,6-pentamethyl-4-piperidyl) 1,2,3,4-butanetetracarboxylate (ADK STAB (registered trademark) LA52, made by ADEKA) 0.33 part in the curable resin composition (3-1), the same procedure was followed as in Example 2 to obtain a multilayer printed circuit board etc. The obtained multilayer printed circuit board etc. were tested and evaluated for the same items as Example 2. The results are shown in Table 1.

### Example 4

Except for making the tetrakis(1,2,2,6,6-pentamethyl-4-piperidyl) 1,2,3,4-butanetetracarboxylate (ADK STAB (registered trademark) LA52, made by ADEKA) 4 parts in the curable resin composition (3-1), the same procedure was followed as in Example 2 to obtain a multilayer printed circuit board etc. The obtained multilayer printed circuit board etc. were tested and evaluated for the same items as Example 2. The results are shown in Table 1.

### Example 5

Except for replacing the tetrakis(1,2,2,6,6-pentamethyl-4-piperidyl)1,2,3,4-butanetetracarboxylate (ADK STAB (registered trademark) LA52, made by ADEKA) with the hindered amine compound (D-2) comprised of tetrakis(2,2,6,6-tetramethyl-4-piperidyl)1,2,3,4-butanetetracarboxylate (ADK STAB (registered trademark) LA57, made by ADEKA) in 1 part in the curable resin composition (B-1), the same procedure was followed as in Example 2 to obtain a multilayer printed circuit board etc. The obtained multilayer printed circuit board etc. were tested and evaluated for the same items as Example 2. The results are shown in Table 1.

### Example 6

Except for replacing the tetrakis(1,2,2,6,6-pentamethyl-4-piperidyl) 1,2,3,4-butanetetracarboxylate (ADK STAB (registered trademark) LA52, made by ADEKA) with the hindered amine compound (D-3) comprised of a condensate of 1,2,3,4-butanetetracarboxylic acid, 1,2,2,6,6-pentamethyl-4-piperidinol, and β,β,β,β-tetramethyl-3,9-(2,4,8,10-tetraoxaspiro[5,5]undecane) diethanol (ADK STAB (registered trademark) LA63, made by ADEKA) in 1 part in the curable resin composition (B-1), the same procedure was followed as in Example 2 to obtain a multilayer printed circuit board etc. The obtained multilayer printed circuit board etc. were tested and evaluated for the same items as Example 2. The results are shown in Table 1.

### Example 7

Except for changing the dipping time while shaking of the laminate in the aqueous solution of a permanganate from 30 minutes to 60 minutes in the oxidation treatment step, the same procedure was followed as in Example 2 to obtain a multilayer printed circuit board etc. The obtained multilayer printed circuit board etc. were tested and evaluated for the same items as Example 2. The results are shown in Table 1.

### Comparative Example 1

Except for not adding tetrakis(1,2,2,6,6-pentamethyl-4-piperidyl) 1,2,3,4-butanetetracarboxylate (ADK STAB (registered trademark) LA52, made by ADEKA) in the curable resin composition (B-1), the same procedure was followed as in Example 2 to obtain a multilayer printed circuit board etc. The obtained multilayer printed circuit board etc. were tested and evaluated for the same items as Example 2. The results are shown in Table 1.

### Comparative Example 2

Except for not adding tetrakis(1,2,2,6,6-pentamethyl-4-piperidyl) 1,2,3,4-butanetetracarboxylate (ADK STAB (registered trademark) LA52, made by ADEKA) and making the tris(3,5-di-t-butyl-4-hydroxybenzyl)-isocyanulate (IRGANOX (registered trademark) 3114, made by Ciba Speciality Chemicals) 3 parts in the curable resin composition (B-1), the same procedure was followed as in Example 2 to obtain a multilayer printed circuit board etc. The obtained multilayer printed circuit board etc. were tested and evaluated for the same items as Example 2. The results are shown in Table 1.

### Comparative Example 3

Except for making the tetrakis(1,2,2,6,6-pentamethyl-4-piperidyl) 1,2,3,4-butanetetracarboxylate (ADK STAB (registered trademark) LA52, made by ADEKA) 1 part and not adding the tris(3,5-di-t-butyl-4-hydroxybenzyl)-isocyanulate (IRGANOX (registered trademark) 3114, made by Ciba Speciality Chemicals) in the curable resin composition (B-1), the same procedure was followed as in Example 2 to obtain a multilayer printed circuit board etc. The obtained multilayer printed circuit board etc. were tested and evaluated for the same items as Example 2. The results are shown in Table 1.

### Comparative Example 4

Except for changing the dipping time while shaking of the laminate in the aqueous solution of a permanganate from 30 minutes to 60 minutes in the oxidation treatment step, the same procedure was followed as in Comparative Example 1 to obtain a multilayer printed circuit board etc. The obtained multilayer printed circuit board etc. were tested and evaluated for the same items as Example 1. The results are shown in Table 1.

TABLE 1
Table 1

| | | Examples | | | | | | Comparative Examples | | | |
|---|---|---|---|---|---|---|---|---|---|---|---|
| | | 2 | 3 | 4 | 5 | 6 | 7 | 1 | 2 | 3 | 4 |
| Composition of curable resin composition (B-1) | | | | | | | | | | | |
| Alicyclic olefin polymer (A-1), | (parts) | 450 | 450 | 450 | 450 | 450 | 450 | 450 | 450 | 450 | 450 |
| solids concentration 22 | | | | | | | | | | | |
| Hindered phenol compound (C) | (parts) | 1 | 1 | 1 | 1 | 1 | 1 | 1 | 3 | — | 1 |
| Hindered amine compound (D-1) | (parts) | 1 | 0.33 | 4 | — | — | 1 | — | — | 1 | — |
| Hindered amine compound (D-2) | (parts) | — | — | — | 1 | — | — | — | — | — | — |
| Hindered amine compound (D-3) | (parts) | — | — | — | — | 1 | — | — | — | — | — |
| Dipping with shaking time in aqueous | (min) | 30 | 30 | 30 | 30 | 30 | 60 | 30 | 30 | 30 | 60 |
| solution of permanganate | | | | | | | | | | | |
| Results of evaluation | | | | | | | | | | | |
| Peel strength | | Excel- | Excel- | Excel- | Excel- | Excel- | Excel- | Excel- | Excel- | Excel- | Excel- |
| | | lent | lent | lent | lent | lent | lent | lent | lent | lent | lent |
| Surface roughness Ra | (nm) | 94 | 138 | 84 | 141 | 88 | 168 | 383 | 272 | 340 | 523 |
| Patternability | | Excel- | Excel- | Excel- | Excel- | Excel- | Excel- | Unac- | Unac- | Unac- | Unac- |
| | | lent | lent | lent | lent | lent | lent | ceptable | ceptable | ceptable | ceptable |

As shown in Table 1, by using the curable resin composition of the present invention, the surface average roughness Ra of the electrical insulating layer becomes small, the adhesion with the conductor layer is excellent, and the etchability is good, so a multilayer printed circuit board which has high density interconnect patterns formed well is obtained (Examples 2 to 6).

Further, even if dipping a laminate obtained by using the curable resin composition of the present invention in an aqueous solution of a permanganate for a long time while shaking it, the surface average roughness Ra of the electrical insulating layer becomes small, there is excellent adhesion with the conductor layer, and the etchability is good, so a multilayer printed circuit board which has high density interconnect patterns formed well is obtained (Example 7). Note that, when using the multilayer printed circuit boards obtained in the examples, preparing microstrip line paths, and measuring the transmission loss (S21) by a network analyzer, in each case the transmission loss was small.

On the other hand, if using a curable resin composition to which no hindered amine compound is added, the surface average roughness Ra of the electrical insulating layer becomes excessive and the obtained multilayer printed circuit board becomes poor in etchability and damaged in interconnect patterns (Comparative Example 1).

Further, if using a curable resin composition to which a hindered amine compound is not added and in which the hindered phenol compound is increased, the surface average roughness Ra of the electrical insulating layer becomes excessive and the obtained multilayer printed circuit board becomes poor in etchability and damaged in interconnect patterns (Comparative Example 2).

On the other hand, if using a curable resin composition to which a hindered amine compound is added and to which a hindered phenol compound is not added, the surface average roughness Ra of the electrical insulating layer becomes excessive and the obtained multilayer printed circuit board becomes poor in etchability and damaged in interconnect patterns (Comparative Example 3).

Further, if dipping a laminate which is obtained by using a curable resin composition to which a hindered amine compound is not added into an aqueous solution of a permanganate for a long time while shaking it, the surface average roughness Ra of the electrical insulating becomes more excessive and the obtained multilayer printed circuit board becomes poor in etchability and damaged in interconnect patterns (Comparative Example 4).

1.-10. (canceled)

11. A curable resin composition comprised of an alicyclic olefin polymer (A) having polar groups, a curing agent (B), a hindered phenol compound (C), and a hindered amine compound (D).

12. The curable resin composition as set forth in claim 11, wherein the polar groups of said alicyclic olefin polymer (A) are of at least one type selected from the group comprised of a carboxyl group, carboxylic acid anhydride group, and phenolic hydroxyl group.

13. The curable resin composition as set forth in claim 11, wherein said curing agent (B) is a compound which has two or more functional groups in its molecule.

14. The curable resin composition as set forth in claim 11, wherein a ratio of said hindered phenol compound (C) and said hindered amine compound (D) is, in weight ratio of the compound (C)/compound (D), 1/0.05 to 1/25.

15. A shaped article obtained by forming the curable resin composition as set forth in claim 11 into a sheet shape or a film shape.

16. A cured article obtained by curing the curable resin composition as set forth in claim 11.

17. A cured article obtained by curing the sheet-shaped or film-shaped shaped article as set forth in claim 15.

18. A surface treated cured article obtained by roughening the surface of the cured article as set forth in claim 16 by an aqueous solution of a permanganate, then electrolessly plating the roughened surface.

19. A laminate obtained by laminating a board which has a conductor layer on its surface and the cured article as set forth in claim 6.

20. A multilayer circuit board obtained by further forming a conductor layer on the layer comprised of the cured article or surface treated cured article of the laminate as set forth in claim 19.

21. An electronic device which is provided with the multilayer circuit board as set forth in claim 20.

22. A laminate obtained by laminating a board which has a conductor layer on its surface and the surface treated cured article as set forth in claim 18.

23. A multilayer circuit board obtained by further forming a conductor layer on the layer comprised of the cured article or surface treated cured article of the laminate as set forth in claim 22.

24. An electronic device which is provided with the multilayer circuit board as set forth in claim 23.
